(19) United States
(12) Patent Application Publication
(10) Pub. No.: US 2022/0190305 A1
(43) Pub. Date: Jun. 16, 2022

(54) EVAPORATION SYSTEM AND EVAPORATION METHOD

(71) Applicant: WUHAN CHINA STAR OPTOELECTRONICS SEMICONDUCTOR DISPLAY TECHNOLOGY CO., LTD., Wuhan (CN)

(72) Inventor: Kunsong Ma, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 17/263,121

(22) PCT Filed: Jul. 22, 2020
(86) PCT No.: PCT/CN2020/103398

§ 371 Date: Jan. 25, 2021

(30) Foreign Application Priority Data
Jun. 24, 2020 (CN) 202010590351.8

(51) Int. Cl. H01L 51/56; C23C 14/24; C23C 14/04; C23C 14/56; H01L 51/00

(52) U.S. Cl. CPC H01L 51/56; C23C 14/24; C23C 14/042; H01L 51/0012; H01L 51/001; H01L 51/0011; C23C 14/568

(57) ABSTRACT

An evaporation system and an evaporation method are provided. The present disclosure can accelerate production cycle, reduce production cost, and improve product quality by disposing an evaporation source vertically in a vacuum chamber and arranging a plurality of substrates on both sides of the evaporation source to perform evaporation on the substrates on the both sides.

### FIELD OF INVENTION

The present disclosure relates to the field of display technologies, and more particularly, to an evaporation system and an evaporation method.

### BACKGROUND OF INVENTION

Light-emitting layers of organic light-emitting display devices (OLEDs) are manufactured by evaporation processes. At present, evaporation equipments are usually designed to make a structure having multiple film layers to be formed by evaporation in a same chamber.

Technical problem: since evaporation is performed in a vacuum environment, a very long time is required for exchanging and supplying materials. Especially for metal coating chambers, high temperature point sources are included and only one substrate can be deposited at a time, thereby affecting acceleration of production cycle. Evaporating a plurality of materials in a same chamber is also prone to cause cross-contamination between each other, thereby affecting quality of devices.

Therefore, it is necessary to provide an evaporation system and an evaporation method to accelerate production cycle, reduce production cost, and improve product quality.

### SUMMARY OF INVENTION

In order to solve the above technical problems, the present disclosure provides an evaporation system and an evaporation method to accelerate production cycle, reduce production cost, and improve product quality.

Specifically, in order to realize the above objectives, the present disclosure provides an evaporation system. The evaporation system includes: a handling device configured to carry and transport a plurality of substrates to be deposited; and a first vacuum chamber configured to receive the substrates and perform evaporation on the substrates vertically. Wherein, the first vacuum chamber includes: a first inlet, wherein the handling device horizontally transports the substrates to the first inlet; a flipping device configured to reverse the substrates from a horizontal state to a vertical state; an evaporation source disposed vertically in a middle of the first vacuum chamber, wherein the substrates after being flipped are arranged in parallel to the evaporation source and disposed on both sides of the evaporation source; and a first outlet, wherein the substrates after being deposited are transported out of the first outlet. Wherein, the both sides of the evaporation source are provided with jet outlets, and a center of the jet outlets is consistent with a center of the substrates to simultaneously perform evaporation on the substrates positioned on the both sides of the evaporation source.

Further, the handling device includes: a slideway; and a carrier slidably connected to the slideway.

Further, the evaporation system also includes an alignment system configured to align the substrates to be deposited with a first mask, place the substrates on the carrier, and attach the substrates to the carrier.

Further, the substrates and the handling device are in the vertical state in the first vacuum chamber, and the substrates and the handling device are in the horizontal state before entering the first vacuum chamber.

Further, the evaporation system also includes: an exchanging device configured to receive the substrates after they are deposited from the first outlet, replace a first mask of the substrates with a second mask, align, and transport the substrates to a second vacuum chamber for another evaporation; wherein the second vacuum chamber includes: a second inlet configured to receive the substrates having the second mask; a flipping device configured to reverse the substrates from a horizontal state to a vertical state; another evaporation source disposed vertically in a middle of the second vacuum chamber, wherein the substrates after being flipped are arranged in parallel to the another evaporation source and disposed on both sides of the another evaporation source; and a second outlet, configured to transport the substrates finishing evaporation out of the second outlet.

Further, the evaporation source includes: a plurality of nozzles disposed at the jet outlets; a main structure provided with an evaporation material, a heating system, and a water cooling system inside; and a diversion device disposed on the main structure and configured to transport the evaporation material which has been heated to the nozzles.

Further, the diversion device is perpendicular to or in parallel to the main structure.

Further, the first vacuum chamber includes a plurality of sub vacuum chambers connected to each other by paving another slideway, and the evaporation source is slidably connected to the another slideway to perform evaporation in the sub vacuum chambers.

Further, the water cooling system includes a water inlet and a water outlet, and water velocities in the water inlet and the water outlet are same to allow the water cooling system to remain in a dynamic equilibrium state.

An embodiment of the present disclosure further provides an evaporation method. The method includes following steps: providing the evaporation system; aligning the substrates to be deposited with the first mask and attaching the substrates to the carrier; transporting the substrates to the plurality of sub vacuum chambers of the first vacuum chamber, wherein the substrates are disposed horizontally on the both sides of the evaporation source; and moving the evaporation source in the sub vacuum chambers and performing evaporation on the substrates.

Beneficial effect: the beneficial effects of the present disclosure are that the evaporation system and the evaporation method are provided. The present disclosure can accelerate production cycle, reduce production cost, and improve product quality by disposing an evaporation source vertically in a vacuum chamber and arranging a plurality of substrates on both sides of the evaporation source to perform evaporation on the substrates on the both sides. In addition, the present disclosure makes the vacuum chamber have a plurality of sub vacuum chambers, so further, evaporation can be performed on the plurality of substrates, and cost is reduced by performing evaporation with one evaporation source in different sub vacuum chambers.

### DESCRIPTION OF DRAWINGS

In order to more clearly describe the technical solutions in the embodiments of the present disclosure, the following will briefly introduce the accompanying drawings used in the description of the embodiments. Obviously, the accompanying drawings described below are only part of the embodiments of the present disclosure, from which those skilled in the art can derive further drawings without making any inventive efforts.

FIG. 1 is a schematic planar diagram of an evaporation system according to an embodiment of the present disclosure.

FIG. 2 is a schematic attached structural diagram of a substrate, a mask, and a carrier according to an embodiment of the present disclosure.

FIG. 3 is a perspective view of a first vacuum chamber according to an embodiment of the present disclosure.

FIG. 4 is a schematic structural diagram of an evaporation source according to an embodiment of the present disclosure.

FIG. 5 is a planar diagram of nozzles according to an embodiment of the present disclosure.

FIG. 6 is a schematic structural diagram of evaporation on both sides of the evaporation source according to an embodiment of the present disclosure.

FIG. 7 is a perspective view of a first vacuum chamber having a vertical structure according to an embodiment of the present disclosure.

FIG. 8 is a schematic structural diagram of a substrate and a handling device in a vertical state according to an embodiment of the present disclosure.

FIG. 9 is a schematic planar diagram of a second vacuum chamber according to an embodiment of the present disclosure.

100. evaporation system; 10. substrate; 11. mask;

101. handling device; 102. first vacuum chamber; 1011. slideway;

1012. carrier; 1022. evaporation source; 1024. nozzle;

1022-1. main structure; 1022-2. diversion device;

1021. sub vacuum chamber; 1022-3. heating system; 1022-4. water cooling system;

1022-5. water inlet; 1022-6. water outlet; 1022-7. jet outlet;

1023. slideway; 103. second vacuum chamber.

### DETAILED DESCRIPTION OF PREFERRED EMBODIMENTS

The specific embodiments described with reference to the attached drawings are all exemplary and are intended to illustrate and interpret the present disclosure. In the description of the present disclosure, it should be understood that terms such as upper, lower, front, rear, left, right, inside, outside, side, as well as derivative thereof should be construed to refer to the orientation as described or as shown in the drawings under discussion. The elements names mentioned in the present disclosure, such as first, second, etc., only distinguish different elements and can be better expressed. The identical or similar reference numerals constantly denote the identical or similar elements or elements having the identical or similar functions in the drawings.

Embodiments of the present disclosure will be described in detail herein with reference to the accompanying drawings. The present disclosure may be embodied in many different forms and should not be construed as being limited to the specific embodiments set forth herein. The embodiments of the present disclosure are provided to explain the practical application of the present disclosure, so that those skilled in the art can understand various embodiments of the present disclosure and various modifications suitable for a specific intended application.

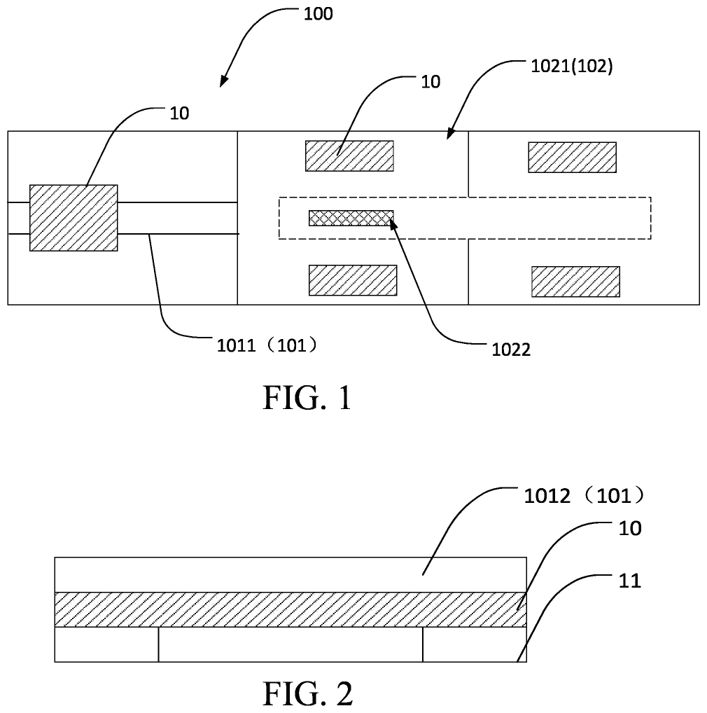

As shown in FIG. 1, the present disclosure provides an evaporation system 100 including a handling device 101, a first vacuum chamber 102, and an alignment system.

As shown in FIG. 2, the alignment system is configured to align one substrate 10 to be deposited with a first mask 11, place the substrate 10 on a carrier 1012, and attach the substrate 10 to the carrier 1012.

The handling device 101 is configured to carry and transport the substrate 10 to be deposited. The handling device 101 includes a slideway 1011 and the carrier 1012.

The carrier 1012 is slidably connected to the slideway 1011. In FIG. 1, the substrate 10 is disposed on the carrier 1012, so the carrier 1012 is not shown in a top view.

Continue to refer to FIG. 1, in an embodiment, the first vacuum chamber 102 includes a plurality of sub vacuum chambers 1021.

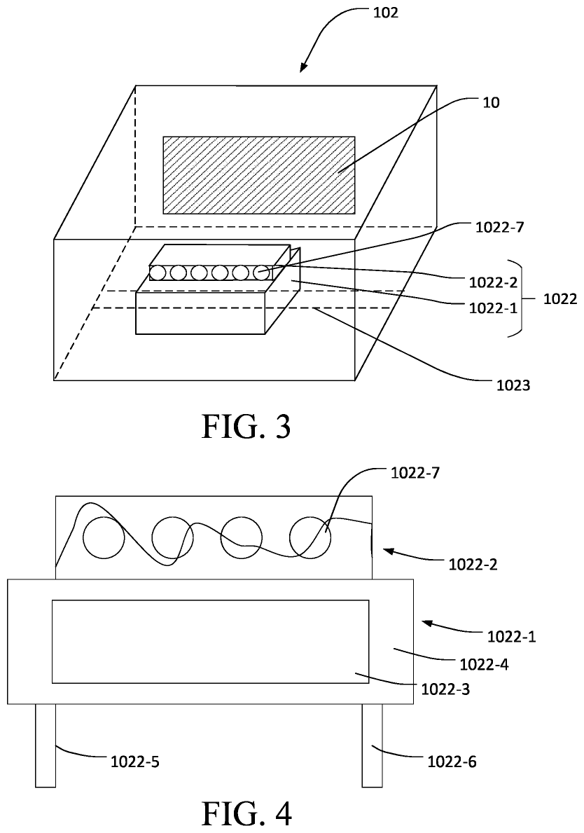

The plurality of sub vacuum chambers 1021 are connected to each other by paving another slideway 1023 (referring to FIG. 3), and an evaporation source 1022 is slidably connected to the another slideway 1023 to perform evaporation in the sub vacuum chambers 1021.

A plurality of substrates 10 to be deposited are disposed vertically on both sides of each of the sub vacuum chambers 1021. The evaporation source 1022 of the first vacuum chamber 102 moves in the plurality of sub vacuum chambers 1021 and performs evaporation on the substrates 10 on the both sides of each of the sub vacuum chambers 1021 respectively, which can perform evaporation on the substrates 10 more rapidly, thereby accelerating production cycle, reducing production cost, and improving product quality.

As shown in FIG. 3, the first vacuum chamber 102 is configured to receive the substrates 10 and perform evaporation on the substrates 10 vertically. The first vacuum chamber 102 includes a first inlet, a flipping device, the evaporation source 1022, and a first outlet.

The handling device 101 horizontally transports the substrates 10 to the first inlet.

The flipping device is configured to reverse the substrates 10 from a horizontal state to a vertical state.

The evaporation source 1022 is disposed vertically in a middle of the first vacuum chamber 102, and the substrates 10 after being flipped are arranged in parallel to the evaporation source 1022 and disposed on the both sides of the evaporation source 1022.

The both sides of the evaporation source 1022 are provided with jet outlets 1022-7 to simultaneously perform evaporation on the substrates 10 on the both sides, thereby improving evaporation efficiency. A center of the jet outlets is consistent with a center of the substrates 10. At last, the substrates 10 after being deposited are transported out of the first outlet.

Referring to FIG. 4, the evaporation source 1022 includes nozzles 1024, a main structure 1022-1, and a diversion device 1022-2.

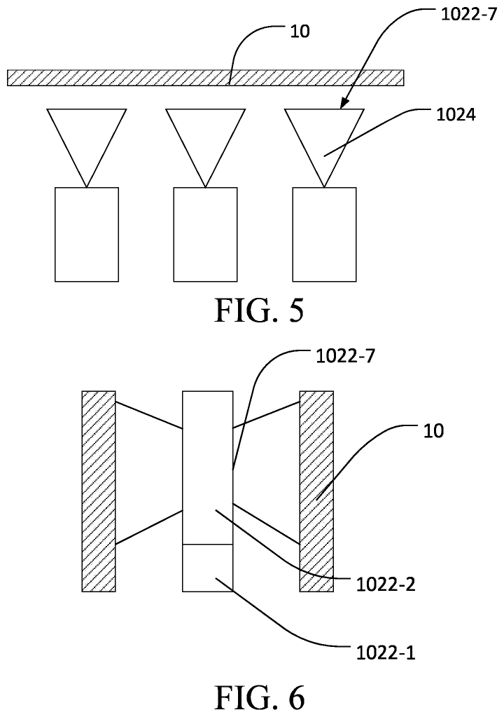

Also referring to FIGS. 5 and 6, the nozzles 1024 are disposed at the jet outlets 1022-7. Opening angles of the nozzles 1024 are adjustable and configured to adjust evaporation angles.

FIG. 5 is a top view of a part of the nozzles 1024, the nozzles 1024 align with an evaporation surface of the substrate 10, and FIG. 5 only shows single-sided evaporation. FIG. 6 is a schematic diagram of double-sided evaporation of an invention point of the present disclosure. Wherein, the nozzles 1024 perform evaporation on the substrates 10 at both sides, so the evaporation efficiency can be improved.

Referring to FIG. 4, the main structure 1022-1 is provided with an evaporation material, a heating system 1022-3, and a water cooling system 1022-4.

The diversion device 1022-2 is disposed on the main structure 1022-1 and configured to transport the evaporation material which has been heated to the nozzles 1024.

The diversion device 1022-2 is perpendicular to or in parallel to the main structure 1022-1.

If the diversion device 1022-2 is parallel to the main structure 1022-1, the evaporation source 1022 is a line source. This structure can cover an entire substrate 10, so the evaporation source 1022 can be fixed. If a size of the evaporation source 1022 is not big enough, the evaporation source 1022 needs to move while performing evaporation so as to deposit the entire substrate 10.

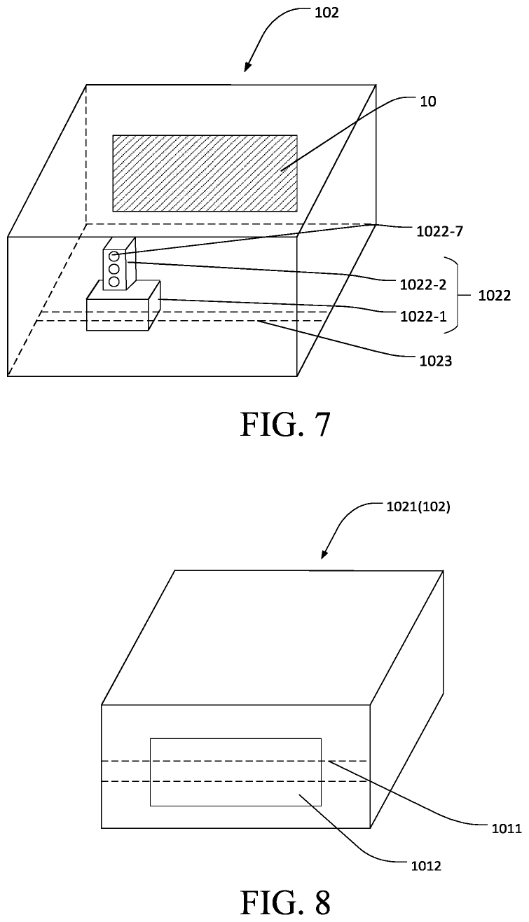

As shown in FIG. 7, if the diversion device 1022-2 is perpendicular to the main structure 1022-1, the evaporation source 1022 is the line source, and a design size of a structure of the evaporation source 1022 is small, so a material utilization rate is higher and cost is lower.

In other embodiments, the evaporation source 1022 may also be the line source.

The heating system 1022-3 includes heating resistors for heating to generate heat.

The water cooling system 1022-4 includes a water inlet 1022-5 and a water outlet 1022-6, and water velocities in the water inlet 1022-5 and the water outlet 1022-6 are same to allow the water cooling system 1022-4 to remain in a dynamic equilibrium state.

The substrates 10 and the handling device 101 are in the horizontal state before entering the first vacuum chamber 102. After being flipped by the flipping device, as shown in FIG. 8, the substrates 10 and the handling device 101 are in the vertical state in the first vacuum chamber 102.

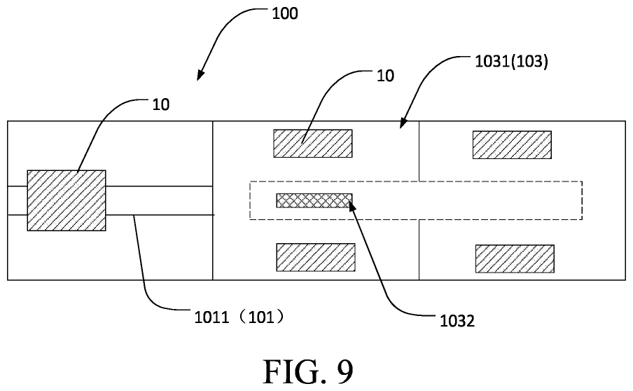

As shown in FIG. 9, in an embodiment, the evaporation system 100 also includes an exchanging device and a second vacuum chamber 103.

The exchanging device is configured to receive the substrates 10 after they are deposited from the first outlet, and replace the first mask 11 with a second mask. Alignment and attachment are performed again by the alignment system, and the substrates 10 are transported to the second vacuum chamber 103 for another evaporation. A film layer deposited in the second vacuum chamber is different from a film layer deposited in the first vacuum chamber 102.

Therefore, in a production line, the second vacuum chamber 103 is arranged downstream of the first vacuum chamber 102.

The second vacuum chamber 103 includes a second inlet, another flipping device, another evaporation source 1032, and a second outlet.

The second inlet is configured to receive the substrates 10 having the second mask.

The flipping device is configured to reverse the substrates 10 from the horizontal state to the vertical state.

The another evaporation source 1032 is disposed vertically in a middle of the second vacuum chamber, and the substrates 10 after being flipped are arranged in parallel to the another evaporation source 1032 and disposed on both sides of the another evaporation source 1032.

A specific structure of the another evaporation source 1032 can refer to a structure of the evaporation source 1022 of the first vacuum chamber 102.

The second outlet is configured to transport the substrates 10 finishing evaporation out of the second outlet. The second vacuum chamber 103 includes a plurality of sub vacuum chambers 1031. The plurality of sub vacuum chambers 1031 are connected to each other by paving another slideway, and the evaporation source 1032 is slidably connected to the slideway to perform evaporation in the sub vacuum chambers 1031.

The present disclosure provides the evaporation system 100, which can accelerate production cycle, reduce production cost, and improve product quality by disposing an evaporation source vertically in a vacuum chamber and arranging a plurality of substrates 10 on both sides of the evaporation source to perform evaporation on the substrates 10 on the both sides. In addition, the present disclosure makes the vacuum chamber have a plurality of sub vacuum chambers, so further, evaporation can be performed on the plurality of substrates 10, and cost is reduced by performing evaporation with one evaporation source in different sub vacuum chambers.

An embodiment of the present disclosure further provides an evaporation method. The method includes following steps.

Providing the evaporation system 100.

Aligning the substrates 10 to be deposited with the first mask 11 and attaching the substrates 10 to the carrier 1012.

Transporting the substrates 10 to the plurality of sub vacuum chambers of the first vacuum chamber 102. Wherein, the substrates 10 are disposed horizontally on the both sides of the evaporation source 1022.

Moving the evaporation source 1022 in the sub vacuum chambers and performing evaporation on the substrates 10.

After evaporation, the substrates 10 are removed out of the first outlet and flipped back to allow the substrates 10 to be disposed horizontally.

The first mask is replaced with the second mask, and then the second mask is aligned with the substrates 10 and attached to the carrier 1012.

The substrates 10 are transported to the second vacuum chamber and vertically disposed on both sides of the second vacuum chamber respectively. The substrates 10 are deposited again by moving the evaporation source 1032.

The technical scope of the present disclosure is not limited to the content in the description, and those skilled in the art can make various variations and modifications to the embodiments without departing from the technical idea of the present disclosure, and these variations and modifications are should be within the scope of the present disclosure.

What is claimed is:

1. An evaporation system, comprising:
a handling device configured to carry and transport a plurality of substrates to be deposited; and
a first vacuum chamber configured to receive the substrates and perform evaporation on the substrates vertically;
wherein the first vacuum chamber comprises:
a first inlet, wherein the handling device horizontally transports the substrates to the first inlet;
a flipping device configured to reverse the substrates from a horizontal state to a vertical state;
an evaporation source disposed vertically in a middle of the first vacuum chamber, wherein the substrates after being flipped are arranged in parallel to the evaporation source and disposed on both sides of the evaporation source; and
a first outlet, wherein the substrates after being deposited are transported out of the first outlet;
wherein the both sides of the evaporation source are provided with jet outlets, and a center of the jet outlets is consistent with a center of the substrates to simultaneously perform evaporation on the substrates positioned on the both sides of the evaporation source.

2. The evaporation system according to claim 1, wherein the handling device comprises:
a slideway; and
a carrier slidably connected to the slideway.

3. The evaporation system according to claim 2, further comprising:
an alignment system configured to align the substrates to be deposited with a first mask, place the substrates on the carrier, and attach the substrates to the carrier.

4. The evaporation system according to claim 2, wherein the substrates and the handling device are in the vertical state in the first vacuum chamber; and
the substrates and the handling device are in the horizontal state before entering the first vacuum chamber.

5. The evaporation system according to claim 1, further comprising:
an exchanging device configured to receive the substrates after they are deposited from the first outlet, replace a first mask of the substrates with a second mask, align, and transport the substrates to a second vacuum chamber for another evaporation;
wherein the second vacuum chamber comprises:
a second inlet configured to receive the substrates having the second mask;
another flipping device configured to reverse the substrates from the horizontal state to the vertical state;
another evaporation source disposed vertically in a middle of the second vacuum chamber, wherein the substrates after being flipped are arranged in parallel to the another evaporation source and disposed on both sides of the another evaporation source; and
a second outlet, configured to transport the substrates finishing evaporation out of the second outlet.

6. The evaporation system according to claim 1, wherein the evaporation source comprises:
a plurality of nozzles disposed at the jet outlets;
a main structure provided with an evaporation material, a heating system, and a water cooling system inside; and
a diversion device disposed on the main structure and configured to transport the evaporation material which has been heated to the nozzles.

7. The evaporation system according to claim 6, wherein the diversion device is perpendicular to or in parallel to the main structure.

8. The evaporation system according to claim 1, wherein the first vacuum chamber comprises a plurality of sub vacuum chambers connected to each other by paving a slideway, and the evaporation source is slidably connected to the slideway to perform evaporation in the sub vacuum chambers.

9. The evaporation system according to claim 6, wherein the water cooling system comprises a water inlet and a water outlet, and water velocities in the water inlet and the water outlet are same to allow the water cooling system to remain in a dynamic equilibrium state.

10. An evaporation method, comprising:
providing an evaporation system, wherein the evaporation system comprises: a handling device configured to carry and transport a plurality of substrates to be deposited; and a first vacuum chamber configured to receive the substrates and perform evaporation on the substrates vertically; wherein the first vacuum chamber comprises: a first inlet, wherein the handling device horizontally transports the substrates to the first inlet; a flipping device configured to reverse the substrates from a horizontal state to a vertical state; an evaporation source disposed vertically in a middle of the first vacuum chamber, wherein the substrates after being flipped are arranged in parallel to the evaporation source and disposed on both sides of the evaporation source; and a first outlet, wherein the substrates after being deposited are transported out of the first outlet; wherein the both sides of the evaporation source are provided with jet outlets, and a center of the jet outlets is consistent with a center of the substrates to simultaneously perform evaporation on the substrates positioned on the both sides of the evaporation source;
aligning the substrates to be deposited with a first mask and attaching the substrates to a carrier;
transporting the substrates to a plurality of sub vacuum chambers of the first vacuum chamber, wherein the substrates are disposed horizontally on the both sides of the evaporation source; and
moving the evaporation source in the sub vacuum chambers and performing evaporation on the substrates.

11. The evaporation method according to claim 10, wherein the handling device comprises:
a slideway; and
the carrier slidably connected to the slideway.

12. The evaporation method according to claim 11, further comprising an alignment system configured to align the substrates to be deposited with the first mask, place the substrates on the carrier, and attach the substrates to the carrier.

13. The evaporation method according to claim 11, wherein the substrates and the handling device are in the vertical state in the first vacuum chamber; and
the substrates and the handling device are in the horizontal state before entering the first vacuum chamber.

14. The evaporation method according to claim 10, further comprising an exchanging device configured to receive the substrates after they are deposited from the first outlet, replace the first mask of the substrates with a second mask, align, and transport the substrates to a second vacuum chamber for another evaporation;
wherein the second vacuum chamber comprises:
a second inlet configured to receive the substrates having the second mask;
another flipping device configured to reverse the substrates from the horizontal state to the vertical state;
another evaporation source disposed vertically in a middle of the second vacuum chamber, wherein the substrates after being flipped are arranged in parallel to the another evaporation source and disposed on both sides of the another evaporation source; and
a second outlet, configured to transport the substrates finishing evaporation out of the second outlet.

15. The evaporation method according to claim 10, wherein the evaporation source comprises:
a plurality of nozzles disposed at the jet outlets;
a main structure provided with an evaporation material, a heating system, and a water cooling system inside; and
a diversion device disposed on the main structure and configured to transport the evaporation material which has been heated to the nozzles.

16. The evaporation method according to claim 15, wherein the diversion device is perpendicular to or in parallel to the main structure.

17. The evaporation method according to claim 10, wherein the first vacuum chamber comprises the plurality of sub vacuum chambers connected to each other by paving a slideway, and the evaporation source is slidably connected to the slideway to perform evaporation in the sub vacuum chambers.

18. The evaporation method according to claim 15, wherein the water cooling system comprises a water inlet and a water outlet, and water velocities in the water inlet and the water outlet are same to allow the water cooling system to remain in a dynamic equilibrium state.
